(19) United States
(12) Patent Application Publication
(10) Pub. No.: US 2008/0224160 A1
(43) Pub. Date: Sep. 18, 2008

(54) High-power light emitting diode and method of manufacturing the same

(75) Inventors: Myung Whun Chang, Seoul (KR); Jong Myeon Lee, Gwacheon (KR); Hyong Sik Won, Suwon (KR); Youn Gon Park, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/003,275

(22) Filed: Dec. 21, 2007

(30) Foreign Application Priority Data
Mar. 13, 2007 (KR) 10-2007-0024536

(51) Int. Cl. H01L 33/00

(52) U.S. Cl. 257/98; 438/65; 257/E33.072; 257/E33.058

(57) ABSTRACT

Provided is a method of manufacturing a high-power LED package, the method including the steps of: preparing a mold having an irregularity pattern; providing a transparent resin solid having an irregularity pattern provided on the surface thereof by using the mold; preparing an irregularity film with the irregularity pattern by cutting a portion of the transparent resin solid; preparing an LED package structure having a cavity in which an LED chip is mounted; filling transparent liquid resin into the cavity having the LED chip mounted therein; mounting the irregularity film on the transparent liquid resin such that the irregularity film projects from the cavity at a predetermined height; and curing the transparent liquid resin having the irregularity film mounted thereon. The irregularity pattern of the irregularity film projects from the cavity at a predetermined height.

### CROSS-REFERENCE TO RELATED APPLICATIONS

This application claims the benefit of Korean Patent Application No. 10-2007-0024536 filed with the Korea Intellectual Property Office on Mar. 13, 2007, the disclosure of which is incorporated herein by reference.

### BACKGROUND OF THE INVENTION

1. Field of the Invention

The present invention relates to a high-power light emitting diode (LED) and a method of manufacturing the same, which can enhance optical efficiency.

2. Description of the Related Art

In general, LEDs are semiconductor light emitting devices which emit light when a current flows, and convert electric energy into light energy through a PN junction diode composed of GaAs and GaN optical semiconductor.

The light emitted from the LEDs ranges from red light (630-700 nm) to blue-violet light (400 nm), including green and white lights. The LEDs have advantages such as low power consumption, high efficiency, long lifespan and so on, compared with existing light sources such as incandescent lamps or fluorescent lamps. A demand for the LEDs is continuously increasing.

Recently, the application range of the LEDs is gradually expanded from small-sized lighting devices for mobile terminals into indoor and outdoor lighting devices, light devices for vehicles, and backlights for large-sized LCD (Liquid Crystal Display).

Depending on the use and a required shape, the LEDs are provided in the form of package. In general, LED packages are manufactured by the following process. First, an LED chip is mounted on a substrate or lead frame where an electrode pattern is formed, and a terminal of the chip is electrically connected to the electrode pattern (or lead). Then, a resin package portion is formed on the substrate or lead frame having the LED chip mounted thereon, by using epoxy, silicon, or a combination of epoxy and silicon.

FIG. 1A is a cross-sectional view of a conventional high-power LED package, and FIG. 1B is a schematic perspective view of the conventional high-power LED package.

As shown in the drawings, the conventional high-power LED package 10 includes an upper package substrate 11a having a circular cavity formed therein and a lower package substrate 11b having lead frames 12a and 12b.

On the lower package substrate 11b, an LED chip 15 is mounted so as to be connected to the respective lead frames 12a and 12b. One electrode of the LED chip 15 is connected to the lead frame 12b through a wire. In this case, the mounting may be performed by a flip-chip bonding method.

The upper package substrate 11a has a circular reflecting plate 13 provided on the side wall of the cavity and a transparent resin package portion 18 filled in the cavity such that the transparent resin package portion 18 transmits light emitted from the LED chip 15 while protecting the LED chip 15 and the wire.

On the resin package portion 18, a lens 30 is provided to radiate the light emitted from the LED chip 15 into the outside.

The resin package portion 18 is a very important element which has an effect upon light emission efficiency of the LED package 10. That is, when the light emitted from the LED chip 13 is extracted into the outside, the extracted amount of light may significantly differ depending on the optical characteristic (specifically, a refractive index) and shape of a constituent material composing the resin package portion 18.

In particular, since the transparent resin, such as epoxy resin or silicon resin, composing the resin package portion 18 has a slightly higher refractive index (for example, epoxy resin: 1.5) than that of the external air, an amount of light which is substantially extracted is limited by a light-extraction critical angle.

In the conventional LED package constructed in such a manner, a circular reflecting plate 13 and a dome-shaped lens 30 are provided to increase light extraction efficiency, as shown in FIG. 2.

However, in a case of flash or backlight LED where an ultra-slim product should be used, a flat lens structure or a lens structure with a small height is adopted. In such a flat structure, a considerable reduction in amount of extracted light is caused by Fresnel reflection loss.

### SUMMARY OF THE INVENTION

An advantage of the present invention is that it provides a high-power LED package and a method of manufacturing the same, which can enhance optical efficiency without using a lens.

Additional aspects and advantages of the present general inventive concept will be set forth in part in the description which follows and, in part, will be obvious from the description, or may be learned by practice of the general inventive concept.

According to an aspect of the invention, a method of manufacturing a high-power LED package comprises the steps of: preparing a mold having an irregularity pattern; providing a transparent resin solid having an irregularity pattern provided on the surface thereof by using the mold; preparing an irregularity film with the irregularity pattern by cutting a portion of the transparent resin solid; preparing an LED package structure having a cavity in which an LED chip is mounted; filling transparent liquid resin into the cavity having the LED chip mounted therein; mounting the irregularity film on the transparent liquid resin such that the irregularity film projects from the cavity at a predetermined height; and curing the transparent liquid resin having the irregularity film mounted thereon. The irregularity pattern of the irregularity film projects from the cavity at a predetermined height.

Preferably, the preparing of the mold includes the steps of: preparing a substrate; forming a photoresist (PR) pattern on the substrate; etching the substrate with the PR pattern set to a mask; and removing the PR pattern remaining on the substrate.

Preferably, the providing of the transparent resin solid includes the steps of: filing transparent liquid resin into the mold; curing the transparent liquid resin so as to form a transparent resin solid; and separating the transparent resin solid from the mold.

Preferably, in the preparing of the irregularity film, a portion of the transparent resin solid having the irregularity pattern formed thereon is cut at a predetermined thickness.

The method further comprises the steps of: performing UV processing on the surface of the irregularity pattern of the mold; and spraying a release agent onto the surface of the irregularity pattern subjected to the UV processing.

Preferably, as for the release agent, silicon oil or a silane-based compound containing trichlorosilane is used.

Preferably, the preparing of the LED package structure includes the steps of: preparing a cup-shaped package structure having a cavity formed in the upper portion thereof and an electrode structure formed on the bottom surface of the cavity; forming a reflecting plate on the side wall of the cavity; and mounting the LED chip on the bottom surface of the cavity such that a terminal of the LED chip is electrically connected to the electrode structure.

Preferably, in the filling of the transparent liquid resin, the transparent liquid resin is filled in such a manner that the inside of the cavity is perfectly filled with the transparent liquid resin.

According to another aspect of the invention, a method of manufacturing a high-power LED package comprises the steps of: preparing a substrate; applying PR onto the substrate, and forming an irregularity pattern on the substrate through a photolithography process; preparing a mold having a lower surface set to the substrate having the irregularity pattern formed thereon; filling first transparent liquid resin into the mold; curing the first transparent liquid resin so as to form a transparent resin solid; separating the transparent resin solid having the irregularity pattern formed thereon from the mold; cutting a portion of the transparent resin solid at a predetermined thickness so as to form an irregularity film which fits into the size of an LED package structure; filling second transparent liquid resin into a cavity of the LED package structure having an LED chip mounted therein; primarily curing the second transparent liquid resin; mounting the irregularity film on the primarily-cured second transparent liquid resin such that the irregularity film projects from the cavity; and secondarily curing the second transparent resin having the irregularity film mounted thereon.

Preferably, in the filling of the second transparent resin, the inside of the cavity is perfectly filled with the second transparent resin. Further, in the mounting of the irregularity film, the irregularity film is mounted in such a manner that the irregularity pattern surface thereof projects from the surface of the LED package structure.

The method further comprises applying a release agent onto the irregularity pattern surface of the substrate. Preferably, the applying of the release agent may include the steps of: performing UV processing on the irregularity pattern surface; and applying a release agent onto the irregularity pattern surface subjected to the UV processing. As for the release agent, silicon oil or a silane-based compound containing trichlorosilane is used.

Preferably, the first and second transparent liquid resins are formed of the same material.

According to a further aspect of the invention, a high-power LED package comprises an LED package structure having a cavity formed in the upper portion thereof and an electrode structure formed on the bottom surface of the cavity; a reflecting plate formed along the side wall of the cavity; an LED chip that is mounted in the cavity so as to be electrically connected to the electrode structure; and a transparent resin package portion that packages the LED chip within the cavity having the LED chip mounted therein and has an irregularity pattern provided thereon such that the irregularity pattern projects from the surface of the LED package structure.

Preferably, the transparent resin package portion includes: first transparent resin which packages the LED chip and is formed in such a manner that the inside of the cavity is perfectly filled with the first transparent resin; and second transparent resin which is formed on the first transparent resin and has an irregularity pattern provided thereon.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a cross-sectional view of a conventional high-power LED package, and FIG. 1B is a schematic perspective view of the conventional high-power LED package;

FIGS. 2A to 2E are process diagrams sequentially showing a method of manufacturing a high-power LED package according to an embodiment of the invention; and

FIGS. 3A to 3J are process diagrams sequentially showing the method of manufacturing a high-power LED package according to another embodiment of the invention.

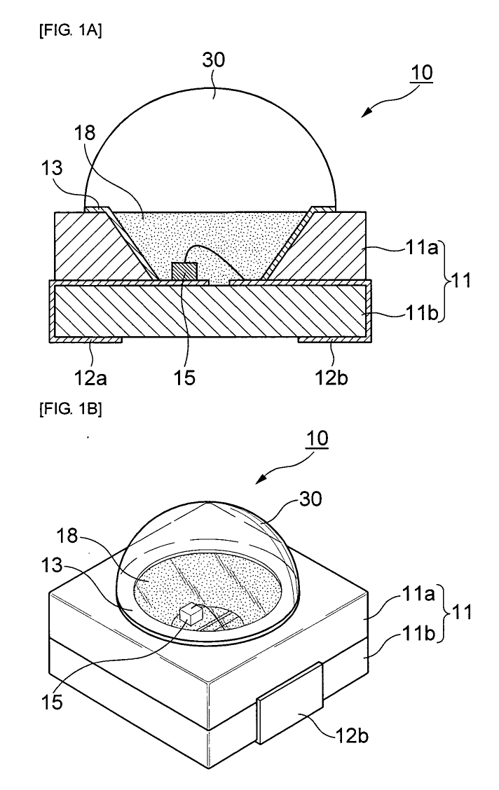

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a high-power LED package and a method of manufacturing the same according to the present invention will be described in detail with reference to the accompanying drawings.

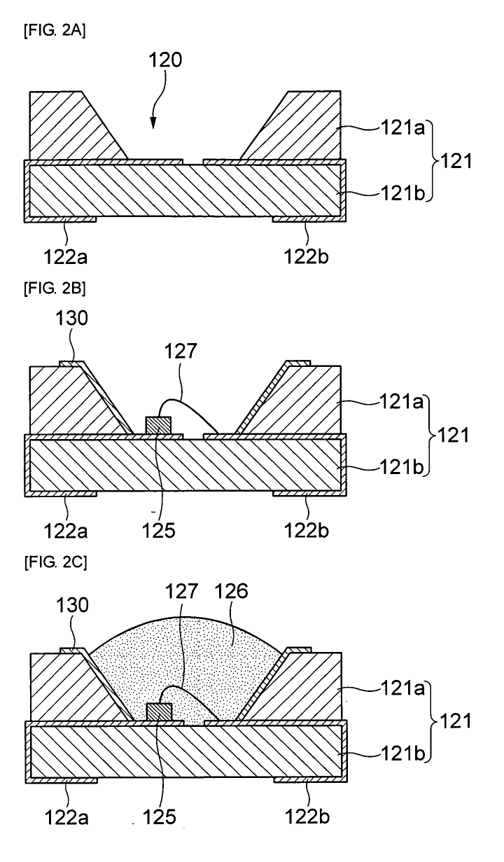

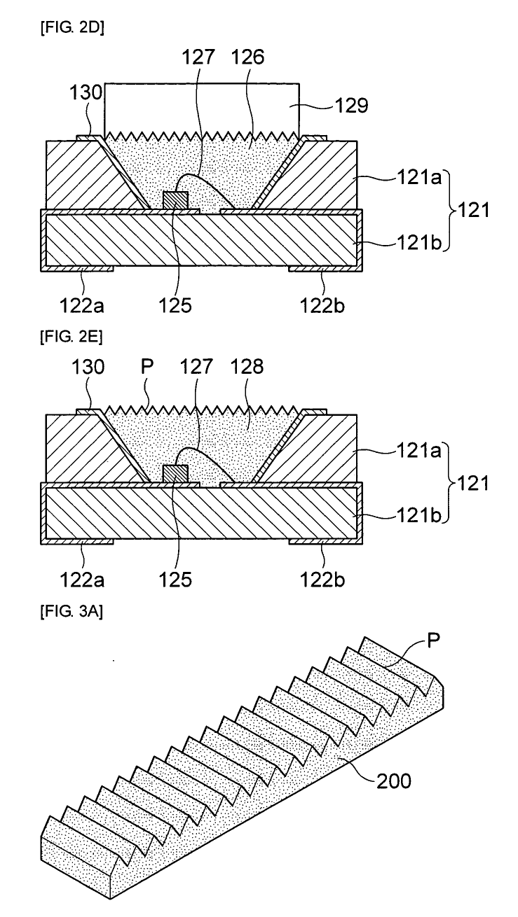

FIGS. 2A to 2E are process diagrams sequentially showing a method of manufacturing a high-power LED package according to an embodiment of the invention.

As shown in FIG. 2A, a cup-shaped LED package structure 121 is prepared, which is composed of an upper substrate 121a having a cavity 120 and a lower substrate 121b having an electrode pattern 122b. The electrode pattern 122b can be considered to be a lead frame.

As shown in FIG. 2B, an LED chip 125 is mounted on the bottom surface of the cavity 120. Then, a terminal (not shown) of the LED chip 125 is electrically connected to the electrode pattern 122b through wire 127, and a reflecting plate 130 is formed on the side wall of the cavity 120.

Next, as shown in FIG. 2C, transparent liquid resin 126 is filled in the cavity 120 of the package structure 121.

In this process, it is preferable that the filing height of the transparent liquid resin 126 is set to be slightly higher than the height of the cavity 120. Then, regardless of the size of a stamp, a desired irregularity pattern can be formed. More preferably, the filled amount of transparent liquid resin 126 is set in such a manner that the transparent liquid resin 126 does not flow into an unexpected region, but can be maintained to be convex due to surface tension.

Subsequently, as shown in FIG. 2D, a stamp 129 having an irregularity pattern provided in a position corresponding to the transparent liquid resin 126 is applied so as to perform imprinting (or stamping) of desired irregularity pattern on the surface of the transparent liquid resin 126, before the transparent liquid resin 126 is cured. At this time, it is preferable that the stamp 129 has a plane structure. The stamp 129 with a plane structure can planarize a curved surface caused by the wetting of the transparent liquid resin 126, thereby preventing disadvantageous optical effects.

In such a state where the stamp 129 is applied, the transparent liquid resin 126 is cured, so that a resin package portion 128 of the LED package structure is formed.

Finally, as the stamp 129 is separated from the resin package portion 128, a uniform irregularity pattern P is formed on the surface of the resin package portion 128, as shown in FIG. 2E.

In the method of manufacturing a high-power LED package according to this embodiment, the irregularity pattern is formed on the surface of the resin package portion, instead of a lens. Therefore, it is possible to enhance light extraction efficiency. Further, as the irregularity pattern for light extraction is formed through the imprinting method, an ultra-slim LED package can be implemented without using a flat lens. Further, since a flat lens is not used, it is possible to prevent the reduction in light extraction efficiency caused by Fresnel reflection loss.

In the method, however, the used number of the stamp, which is used for forming the irregularity pattern on the surface of the resin package portion, is limited to about ten. Therefore, a manufacturing cost increases due to the manufacturing of the stamp.

Further, while the stamp is applied onto the transparent liquid resin so as to transfer an irregularity pattern onto the transparent liquid resin, the transparent liquid resin may leak from the cavity so as to be formed on the package substrate excluding the cavity. In this case, the transparent liquid resin formed on the package substrate should be removed.

Therefore, a method of manufacturing a high-power LED package according to another embodiment of the invention is provided to solve such a problem. That is, an irregularity pattern can be formed without using the stamp, and a film having an irregularity pattern formed thereon is mounted on transparent resin, which makes it possible to prevent the irregularity pattern from being formed in a region excluding the cavity.

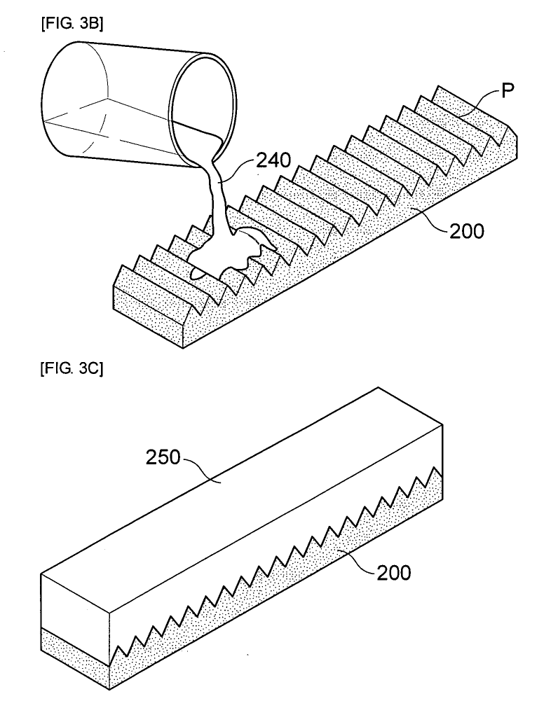

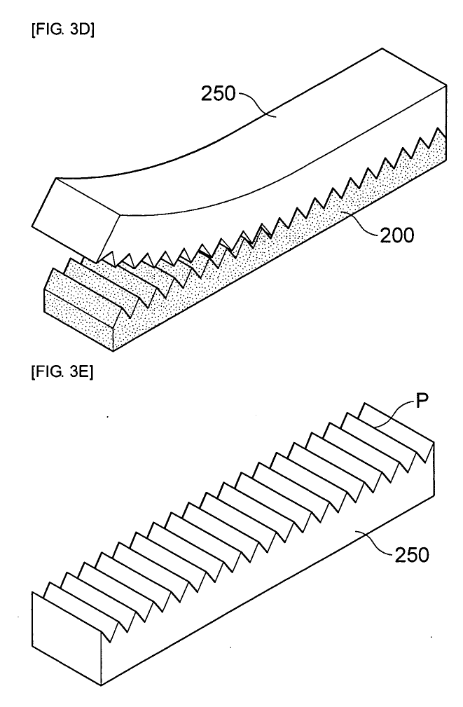

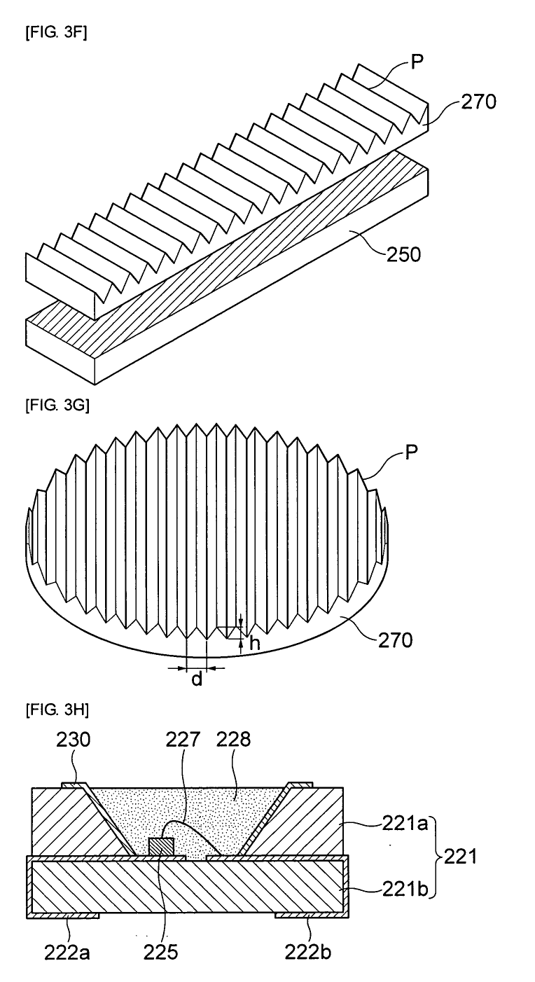

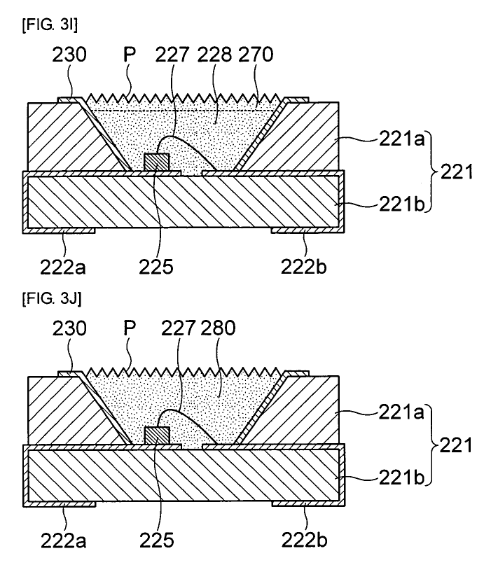

FIGS. 3A to 3J are process diagrams sequentially showing the method of manufacturing a high-power LED package according to another embodiment of the invention.

First, as shown in FIG. 3A, a substrate is prepared, and an irregularity pattern P is formed on the surface of the substrate, thereby preparing a mold 200.

As for the substrate, a silicon substrate may be used. The irregularity pattern P may be formed by a photolithography process. In the photolithography process, photoresist (PR) is applied on the silicon substrate and is then exposed so as to form a PR pattern. Then, an etching process is performed with the PR pattern set to a mask.

Subsequently, as shown in FIG. 3B, transparent liquid resin 240 is poured into the mold 200 and is cured. Then, as shown in FIG. 3C, a transparent resin solid 250 is provided. At this time, the transparent liquid resin 240 may be formed of transparent resin such as silicon resin, epoxy resin, or a combination thereof.

In a process of separating the transparent resin solid, which will be described below, a release agent may be applied onto the surface of the irregularity pattern of the mold 200. The applying of the release agent is performed before the transparent liquid resin 240 is filled.

The applying of the release agent is performed as follows. First, UV processing is performed on the surface of the irregularity pattern P so as to remove bonding. Then, the release agent is applied onto the surface of the irregularity pattern P subjected to the UV processing. As for the release agent, silicon oil or a silane-based compound containing trichlorosilane (heptadecafluoro-1,1,2,2-tetra-hydrodecyl) may be used.

Continuously, as shown in FIGS. 3D and 3E, the transparent resin solid 250 is separated from the mold 200 such that the irregularity pattern P is formed on the surface thereof.

Subsequently, as shown in FIG. 3F, a portion of the transparent resin solid 250 separated from the mold 20 is cut so as to form an irregularity film 270 with a predetermined thickness.

In a general high-power LED package, a cavity of an upper package substrate is formed in a circular shape. Therefore, as shown in FIG. 3G, the irregularity film 270 is cut into a circular shape so as to fit into the shape of the resin package portion formed on the LED package substrate.

In this case, a circular mold may be previously prepared to form the irregularity film 270. Then, the process of cutting the irregularity film into a circular shape may be omitted. That is, a mold which fits into the shape of the high-power LED package is manufactured in advance, and a circular transparent resin solid is formed through the mold. Then, the process of cutting the irregularity film into a circular shape may be omitted.

The irregularity pattern P of the irregularity film 270 may be manufactured in various manners depending on the patterns of the mold 200. Further, the size of the irregularity pattern as well as the shape of the irregularity pattern may have an effect upon the improvement of light extraction efficiency. For example, in the irregularity pattern P having a triangle cross-section, the base length d or the height h of the triangle cross-section may be properly selected, when the irregularity pattern P is designed. Then, it is possible to effectively control light extraction efficiency.

The irregularity film 270 manufactured through the process of FIGS. 3A to 3G is mounted on a cavity of an LED package substrate having an LED chip mounted therein. This will be described in detail with reference to FIGS. 3H to 3J.

First, as shown in FIG. 3H, a cup-shaped LED package structure 221 is provided, in which a cavity 220 is formed on the upper portion thereof and electrode patterns 222a and 222b are provided on the bottom surface of the cavity 220.

In the drawings, it is exemplified that the LED package structure 221 is composed of an upper substrate 221a having the cavity 220 and a lower substrate 221b having the electrode patterns 222a and 222b. Without being limited thereto, however, the LED package structure 221 may be another high-power LED package substrate having a cup structure for mounting chips.

Further, the electrode patterns 222a and 222b may be considered as an electrode structure which is connected to a rear electrode through a conductive via hole. As for the electrode structure, various well-known different structures such as a lead frame and so on may be adopted.

Subsequently, an LED chip 225 is mounted on the bottom surface of the cavity 220, and a terminal (not shown) of the LED chip 225 is electrically connected to the electrode patterns 222a and 222b through wire 227. Further, the connection may be performed by a flip-chip bonding method.

The LED chip 225 may include a submount substrate and an LED chip mounted on the top surface of the submount substrate. The LED chip 225 may be fixed to the lower substrate 221b through an adhesive 224 such as Ag epoxy or eutectic solder.

Continuously, a reflecting plate 230 is formed on the inner side wall of the cavity 220. Then, transparent liquid resin 228 is filled into the cavity 220 of the LED package structure 221 including the reflecting plate 230 such that the cavity 220 is perfectly filled with the transparent liquid resin 228.

As for the transparent liquid resin 228, the same material as the transparent resin for the irregularity film is used. As for the filling method, a well-known process such as a dispensing process or the like may be performed.

Additionally, a defoaming process may be performed in such a manner that bubbles are removed from the transparent liquid resin 228. The defoaming process includes a curing process performed for a predetermined time, and the transparent liquid resin 228 is semi-cured as the curing process is performed for a predetermined time.

Subsequently, as shown in FIG. 3I, the irregularity film 270 is mounted on the semi-cured transparent liquid resin 228. At this time, since the cavity is fully filled with the semi-cured transparent liquid resin 228, the height of the irregularity pattern is set to be larger than that of the cavity.

Further, as the semi-cured transparent liquid resin 228 having the irregularity film 270 mounted thereon is cured into a transparent resin solid, a resin package portion 280 having the irregularity pattern P provided thereon is formed as shown in FIG. 3J.

Through the above-described processes, it is possible to provide the high-power LED package in which the LED chip is mounted in the cavity, the transparent liquid resin for protecting the LED chip is formed, and the irregularity pattern for enhancing optical efficiency is provided on the surface thereof.

In this embodiment, as the irregularity pattern is formed without using a stamp, it is possible to solve the problem of the previous embodiment, where a manufacturing cost increases due to the stamp.

Further, the resin package portion is formed by the method where the irregularity film is separately manufactured and is then mounted on the transparent liquid resin which is previously filled up. Therefore, it is possible to solve the problem of the previous embodiment, where while the irregularity pattern is formed by applying the stamp onto the transparent liquid resin filled in the cavity of the LED package, the transparent liquid resin leaks from the cavity.

According to the present invention, when the high-power LED package is manufactured, the irregularity pattern is formed on the surface of the resin package portion, without forming a lens. Therefore, the high-power LED package is suitable for ultra-slim products, and can enhance light extraction efficiency.

In particular, when the irregularity pattern is formed, the irregularity film is previously formed and is then mounted on the transparent liquid resin which is filled in advance. Therefore, a manufacturing cost can be reduced, and the manufacturing process can be simplified.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a high-power LED package, the method comprising the steps of:
preparing a mold having an irregularity pattern;
providing a transparent resin solid having an irregularity pattern provided on the surface thereof by using the mold;
preparing an irregularity film with the irregularity pattern by cutting a portion of the transparent resin solid;
preparing an LED package structure having a cavity in which an LED chip is mounted;
filling transparent liquid resin into the cavity having the LED chip mounted therein;
mounting the irregularity film on the transparent liquid resin such that the irregularity film projects from the cavity at a predetermined height; and
curing the transparent liquid resin having the irregularity film mounted thereon,
wherein the irregularity pattern of the irregularity film projects from the cavity at a predetermined height.

2. The method according to claim 1, wherein the preparing of the mold includes the steps of:
preparing a substrate;
forming a photoresist (PR) pattern on the substrate;
etching the substrate with the PR pattern set to a mask; and
removing the PR pattern remaining on the substrate.

3. The method according to claim 1, wherein the providing of the transparent resin solid includes the steps of:
filing transparent liquid resin into the mold;
curing the transparent liquid resin so as to form a transparent resin solid; and
separating the transparent resin solid from the mold.

4. The method according to claim 1, wherein in the preparing of the irregularity film, a portion of the transparent resin solid having the irregularity pattern formed thereon is cut at a predetermined thickness.

5. The method according to claim 1 further comprising the steps of:
performing UV processing on the surface of the irregularity pattern of the mold; and
spraying a release agent onto the surface of the irregularity pattern subjected to the UV processing.

6. The method according to claim 5, wherein as for the release agent, silicon oil or a silane-based compound containing trichlorosilane is used.

7. The method according to claim 1, wherein the preparing of the LED package structure includes the steps of:
preparing a cup-shaped package structure having a cavity formed in the upper portion thereof and an electrode structure formed on the bottom surface of the cavity;
forming a reflecting plate on the side wall of the cavity; and
mounting the LED chip on the bottom surface of the cavity such that a terminal of the LED chip is electrically connected to the electrode structure.

8. The method according to claim 1, wherein in the filling of the transparent liquid resin, the transparent liquid resin is filled in such a manner that the inside of the cavity is perfectly filled with the transparent liquid resin.

9. A method of manufacturing a high-power LED package, the method comprising the steps of:
preparing a substrate;
applying PR onto the substrate, and forming an irregularity pattern on the substrate through a photolithography process;
preparing a mold having a lower surface set to the substrate having the irregularity pattern formed thereon;
filling first transparent liquid resin into the mold;
curing the first transparent liquid resin so as to form a transparent resin solid;
separating the transparent resin solid having the irregularity pattern formed thereon from the mold;
cutting a portion of the transparent resin solid at a predetermined thickness so as to form an irregularity film which fits into the size of an LED package structure;
filling second transparent liquid resin into a cavity of the LED package structure having an LED chip mounted therein;
primarily curing the second transparent liquid resin;
mounting the irregularity film on the primarily-cured second transparent liquid resin such that the irregularity film projects from the cavity; and
secondarily curing the second transparent resin having the irregularity film mounted thereon.

10. The method according to claim 9, wherein in the filling of the second transparent resin, the inside of the cavity is perfectly filled with the second transparent resin.

11. The method according to claim 9, wherein in the mounting of the irregularity film, the irregularity film is mounted in such a manner that the irregularity pattern surface thereof projects from the surface of the LED package structure.

12. The method according to claim 9 further comprising the step of:
applying a release agent onto the irregularity pattern surface of the substrate.

13. The method according to claim 12, wherein the applying of the release agent includes the steps of:
performing UV processing on the irregularity pattern surface; and
applying a release agent onto the irregularity pattern surface subjected to the UV processing.

14. The method according to claim 13, as for the release agent, silicon oil or a silane-based compound containing trichlorosilane is used.

15. The method according to claim 9, wherein the first and second transparent liquid resins are formed of the same material.

16. A high-power LED package comprising:
an LED package structure having a cavity formed in the upper portion thereof and an electrode structure formed on the bottom surface of the cavity;
a reflecting plate formed along the side wall of the cavity;
an LED chip that is mounted in the cavity so as to be electrically connected to the electrode structure; and
a transparent resin package portion that packages the LED chip within the cavity having the LED chip mounted therein and has an irregularity pattern provided thereon such that the irregularity pattern projects from the surface of the LED package structure.

17. The high-power LED package according to claim 16, wherein the transparent resin package portion includes:
first transparent resin which packages the LED chip and is formed in such a manner that the inside of the cavity is perfectly filled with the first transparent resin; and
second transparent resin which is formed on the first transparent resin and has an irregularity pattern provided thereon.
